(19) United States
(12) Patent Application Publication
(10) Pub. No.: US 2012/0193810 A1
(43) Pub. Date: Aug. 2, 2012

(54) WIRELESS APPARATUS AND WIRELESS SYSTEM

(75) Inventors: Yukako Tsutsumi, Kawasaki-shi (JP); Hiroki Shoki, Yokohama-shi (JP)

(73) Assignee: KABUSHIKI KAISHA TOSHIBA, Tokyo (JP)

(21) Appl. No.: 13/344,848

(22) Filed: Jan. 6, 2012

(30) Foreign Application Priority Data
Feb. 1, 2011 (JP) 2011-019866

(51) Int. Cl. H01L 23/522

(52) U.S. Cl. 257/774; 257/E23.145

(57) ABSTRACT

According to one embodiment, a wireless apparatus includes an integrated circuit package, a board having a first layer. The integrated circuit package includes an integrated circuit and at least one antenna. The board has a first surface and a second surface opposite to the first surface, the integrated circuit package is mounted on the board and is electrically connected to the board. The first layer is formed on the second surface, a part of the first layer in a first region is formed of a conductor, the first region is a region on which the antenna is projected in a thickness direction of the board, the part of the first layer in the first region is electrically connected to a particular region included in a third region, the third region is formed of a second region included in the board and the first surface.

### CROSS-REFERENCE TO RELATED APPLICATIONS

This application is based upon and claims the benefit of priority from prior Japanese Patent Application No. 2011-019866, filed Feb. 1, 2011, the entire contents of which are incorporated herein by reference.

### FIELD

Embodiments described herein relate generally to a wireless apparatus and a wireless system.

### BACKGROUND

There is a method for providing, on the package substrate of an package with built-in antenna, a metal plate functioning as a radiator connected to an IC chip, and providing another metal plate functioning as a reflector on the package substrate in parallel with the radiator, thereby preventing from being radiated in different directions, and can be radiated in a desired direction.

### BRIEF DESCRIPTION OF THE DRAWINGS

FIG. 1A is a plan view illustrating a wireless apparatus according to a first embodiment;

FIG. 1B is a sectional view illustrating the wireless apparatus of the first embodiment;

FIG. 2 a plan view illustrating another example of an antenna incorporated in the wireless apparatus of the first embodiment;

FIG. 3 is a view useful in explaining how the electric field and current vary depending on whether vias are provided in the wireless apparatus of the first embodiment;

FIG. 4A is a plan view illustrating a wireless apparatus according to a second embodiment;

FIG. 4B is a sectional view illustrating the wireless apparatus of the second embodiment;

FIG. 5A is a plan view illustrating a wireless apparatus according to a third embodiment;

FIG. 5B is a sectional view illustrating the wireless apparatus of the third embodiment;

FIG. 6 is a view useful in explaining how the electric field and current vary depending on whether vias are provided in the wireless apparatus of the third embodiment;

FIG. 7A is a plan view illustrating a wireless apparatus according to a fourth embodiment;

FIG. 7B is a sectional view illustrating the wireless apparatus of the fourth embodiment;

FIG. 8 is a view useful in explaining how the electric field and current vary depending on whether vias are provided in the wireless apparatus of the fourth embodiment;

FIG. 9A is a view illustrating an electric field distribution characteristic of a wireless apparatus assumed when the apparatus has vias;

FIG. 9B is a view illustrating an electric field distribution characteristic of a wireless apparatus assumed when the apparatus has no vias;

FIG. 10A is a view illustrating a current distribution characteristic of a wireless apparatus assumed when the apparatus has vias;

FIG. 10B is a view illustrating a current distribution characteristic of a wireless apparatus assumed when the apparatus has no vias;

FIG. 11A is a view illustrating a radiation pattern cut surface characteristic of a wireless apparatus assumed when the apparatus has vias;

FIG. 11B is a view illustrating a radiation pattern cut surface characteristic of a wireless apparatus assumed when the apparatus has no vias;

FIG. 11C is a view illustrating a radiation pattern cut surface characteristic assumed when only an IC package exists;

FIG. 12A is a plan view illustrating a wireless apparatus according to a modification;

FIG. 12B is a sectional view illustrating the wireless apparatus of the modification;

FIG. 13 is a block diagram illustrating a wireless system including a wireless apparatus according to a fifth embodiment; and

FIG. 14 is a view illustrating an example of the wireless system according to the fifth embodiment.

### DETAILED DESCRIPTION

In general, IC packages are used, mounted on boards. If a conventional IC package with built-in antenna is directly mounted on a board with metal plates provided thereon, currents are induced in the metal plates provided near the antenna, thereby degrading the antenna characteristics.

Also, in general, the boards mounted the IC package with built-in antennas thereon have different thicknesses. If the board is formed sufficiently thick and there is no metal plate near the antenna, current induction will not easily occur to thereby reduce the influence of currents on the antenna. In contrast, if the board is sufficiently thin and there are metal plates on the board, or if IC package terminals, ground and wiring have to be provided around the antenna, the characteristics of the antenna will be varied by them.

Further, the conventional IC-package antenna is dipole antenna with reflector, and is influenced by metal plates existing around it. However, in the prior art, since the influence of the metal plates is not considered, this involves a problem when the IC package is mounted.

In general, according to one embodiment, a wireless apparatus includes an integrated circuit package, a board having a first layer. The integrated circuit package includes an integrated circuit and at least one antenna. The board has a first surface and a second surface opposite to the first surface, the integrated circuit package is mounted on the board and is electrically connected to the board. The first layer is formed on the second surface, a part of the first layer in a first region is formed of a conductor, the first region is a region on which the antenna is projected in a thickness direction of the board, the part of the first layer in the first region is electrically connected to a particular region included in a third region, the third region is formed of a second region included in the board and the first surface.

Wireless apparatuses and wireless systems according to embodiments will now be described with reference to the accompanying drawings. In the embodiments described below, like reference numbers denote like elements, and no duplicate descriptions will be given.

### First Embodiment

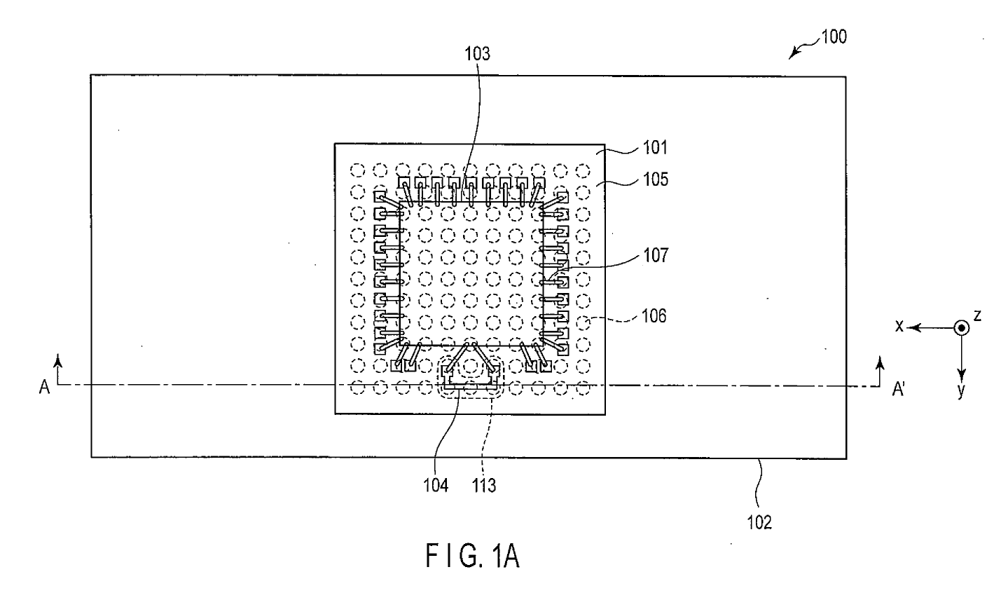

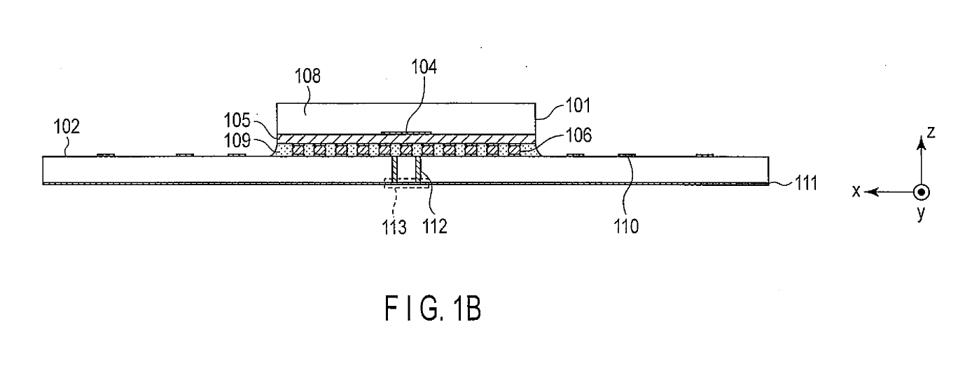

Referring first to FIGS. 1A and 1B, a description will be given of a wireless apparatus according to a first embodiment. FIG. 1A is a top plan view, and FIG. 1B is a sectional view taken along line A-A′ in FIG. 1A.

A wireless apparatus 100 according to the first embodiment includes an integrated circuit (hereinafter, IC) package 101, and a board 102. The IC package 101 includes an IC chip 103, an antenna 104, a package substrate 105, bonding wires 107 and an encapsulation resin 108. The board 102 includes metal plates 110 and a first layer 111. Further, the IC package 101 is electrically connected to the board 102 by external terminals 106.

The IC chip 103 has a structure in which an insulating layer is provided on a substrate formed of, for example, silicon, silicon-germanium, or gallium arsenide, and metal plates of copper, aluminum and/or gold are provided on the insulating layer. Alternatively, the IC chip 103 may include a dielectric substrate, a magnetic material substrate, or a combination thereof. Further, although the IC chip 103 is formed square in FIGS. 1A and 1B, it may be formed rectangular, polygonal or circular, or any other complex shape.

The antenna 104 may be formed of a metal plate provided on the IC chip 103 or on the package substrate 105 contained in the IC package 101. Alternatively, the antenna may be formed of a combination of, for example, a metal plate on the IC chip 103 or the package substrate 105, a bonding wire 107 or bonding wires 107, or a bump or bumps (not shown) that connect the IC chip 103 to the package substrate 105, and a dielectric member. The example of FIG. 1 employs a loop antenna formed of a metal plate on the package substrate 105, a metal plate (not shown) on the IC chip 103, and bonding wires 107.

The package substrate 105 is electrically connected to the external terminals 106 of the IC package 101 by, for example, soldering. Further, the external terminals 106 are connected to the metal plates 110 on the board 102.

The bonding wires 107 connect the metal plates (not shown) on the IC chip 103 to the metal plates (not shown) on the package substrate 105. The metal plate (not shown) on the IC chip 103 may be aligned with the metal plate formed surface of the package substrate 105, and be coupled to them by flip-chip bonding without using the bonding wires 107.

The encapsulation resin 108 is formed of, for example, a thermosetting molding compound that includes an epoxy resin as a main component, and a silica filler added therein. The encapsulation resin 108 is filled in the IC package 101 to protect the IC.

As shown in FIG. 1B, an under filler 109 is filled in the layer including the external terminals 106. Although the under filler 109 is filled to reinforce the connection between the IC package 101 and the board 102, it may not necessarily be used.

The metal plates 110 are formed for enabling the IC package 101 and other components to be mounted on or connected to the board 102.

The first layer 111 is formed of, for example, a metal, and is provided on a second surface of the board 102 opposite to a first surface thereof on which the IC package 101 is mounted. It is desirable that the first layer 111 be entirely formed of a conductor. However, it is sufficient if the region (first region) of the first layer 111, on which the antenna 104 is projected when it is projected in the thickness direction of the board 102, is at least formed of a conductor. More specifically, in the examples of FIGS. 1A and 1B, the region 113 of the first layer 111, on which the antenna 104 is projected when it is projected toward the board 102 in the Z-axis direction, is at least formed of a conductor.

Further, the board 102 has vias 112 for electrically connecting the first layer 111 to particular regions included in a region (third region) that includes a certain region (second region) included in the board 102, and the first surface of the board 102 with the IC package 101 mounted thereon. More specifically, the vias 112 are formed by plating, with a metal, the inner walls of the holes formed in the board 102. When some components, for example, are provided on the vias 112 formed in the board 102, the via may be filled with a resin or a metal. In the example of FIG. 1B, two vias 112 are formed. However, the number of vias is not limited to two. It is sufficient if at least one via 112 is formed.

Further, in the example of FIG. 1, the antenna 104 is formed bilaterally symmetric. However, it may be formed asymmetric, and may be a dipole antenna, an inverted F antenna, a patch antenna, a dielectric antenna, or other types of antennas.

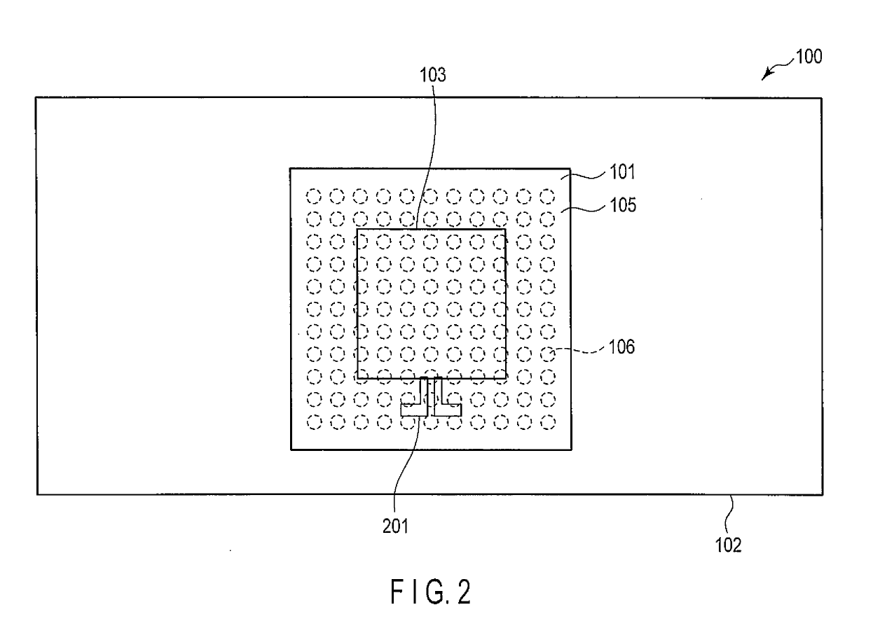

FIG. 2 shows an antenna different in shape from the antenna 104 in FIG. 1A.

In the structure shown in FIG. 2, an antenna 201 is directly connected to the IC chip 103 without using the bonding wires 107, and functions as a dipole antenna.

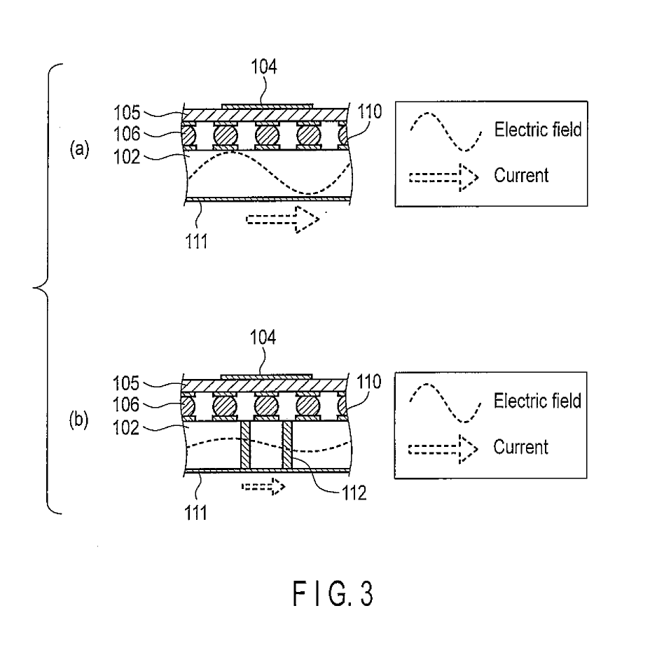

(a) of FIG. 3 shows the electric field and the current that occur when no vias 112 are formed, and (b) of FIG. 3 shows the electric field and the current that occur when the vias 112 are formed.

As shown in (a) of FIG. 3, the board 102 has the space defined by the antenna 104 or metal plate 110 and the first layer 111, in which space a substantial perpendicular electric field occurs in the first layer 111. Further, the current flowing through the antenna 104 causes a current flow parallel with the first layer 111. The thus-generated electric field and current adversely influences the radiation pattern of the antenna 104.

In contrast, in the case shown in (b) FIG. 3, since the vias 112 are formed in the first layer 111, an obstacle occurs at the position of the electric field to thereby suppress the electric field compared to that shown in (a) of FIG. 3. Further, since the current flowing in parallel with the first layer 111 is bifurcated, the current flow is reduced compared to that shown in (a) of FIG. 3. Thus, the electric field and current that occur in the board 102 are suppressed. In addition, since the first layer 111 functions as a shield for suppressing the influence of the metals, components, dielectric substances, etc., mounted on the wireless apparatus 100, it can prevent degradation of the radiation pattern of the antenna.

The first embodiment described above can suppress unnecessary electric field and current that will occur in the substrate, thereby improving the characteristics of the antenna.

### Second Embodiment

A second embodiment differs from the first embodiment in that the former includes a second layer provided in the substrate, and no conductors except for the vias are contained in the region of the second layer, on which the antenna is projected when the antenna is projected in the thickness direction of the board.

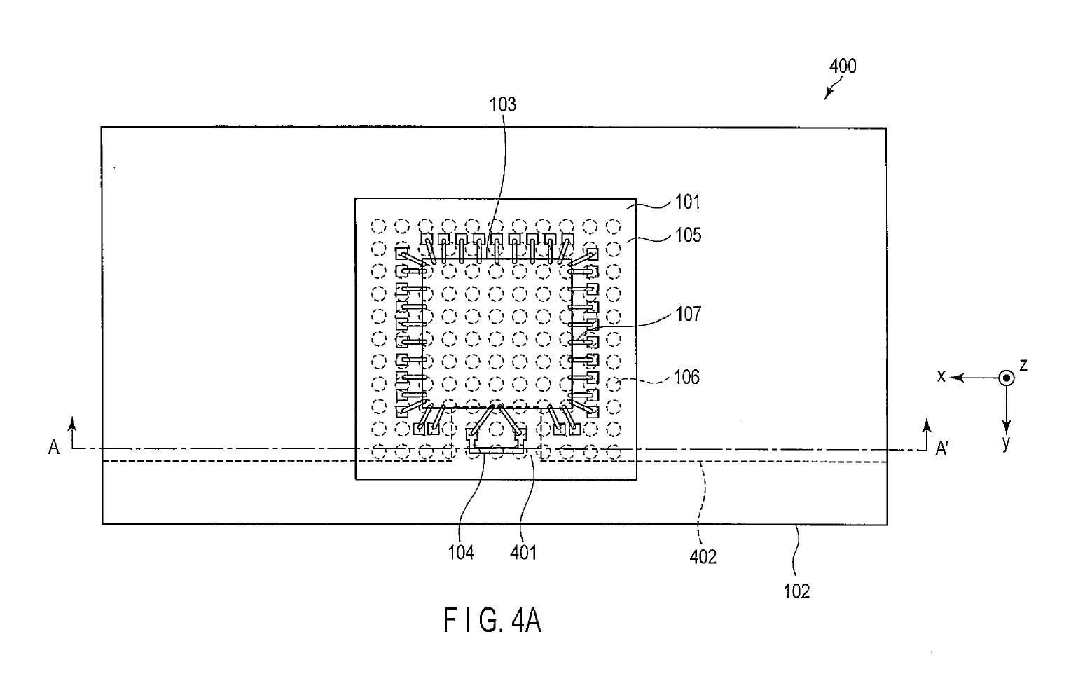

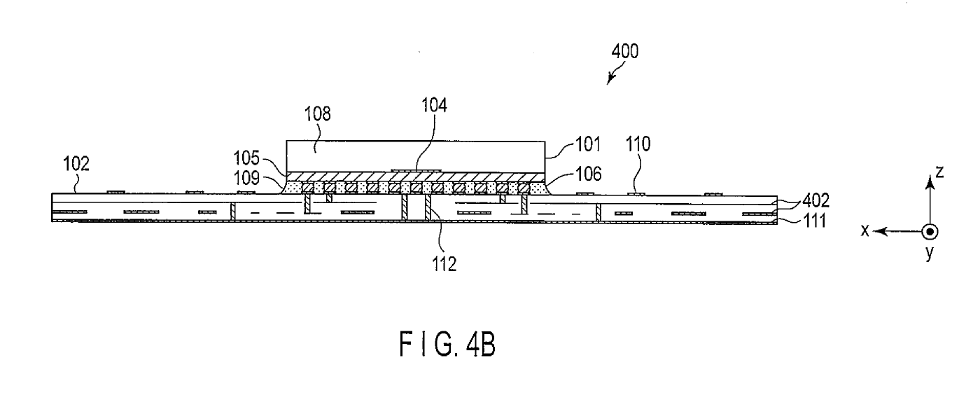

FIGS. 4A and 4B show a wireless apparatus according to the second embodiment. FIG. 4A is a plan view of the wireless apparatus according to the second embodiment, and FIG. 4B is a sectional view taken along line A-A′ in FIG. 4A.

A wireless apparatus 400 of the second embodiment includes an IC package 101 and a board 102. Since the IC package 101 is similar to that of the first embodiment, it will not be described. The board 102 includes a second layer 402 interposed between the first surface of the board 102 provided with the IC package 101, and the first layer 111. The second layer 402 includes a region (fourth region) 401 on which the antenna 104 is projected when it is projected in the thickness direction of the board 102, and this region includes no conductors except for the vias 112 and conductors required to form the vias 112. The second layer 402 can also be used as a ground layer or a wiring layer.

For facilitating the description, the fourth region 401 shown in FIGS. 4A and 4B, will hereinafter be referred to as “a notch 401.”

As shown in FIG. 4B, the vias 112 extend through the board 102 from the first surface to the first layer 111 as the lowest layer. Alternatively, the vias may be stopped at the middle portion of the board 102.

In the above-described second embodiment, since the region of the second layer, on which the antenna 104 is projected when it is projected in the thickness direction of the board 102, contains no conductors, the second layer can be used as a ground or wiring layer. This structure improves the antenna characteristics as in the first embodiment, and simultaneously enhances the degree of freedom in designing the board.

### Third Embodiment

A third embodiment differs from the first embodiment in that in the former, a via or vias are arranged away from each edge or both opposite edges of the notch by distances corresponding to odd multiples of a quarter of the wavelength used for communication, while in the latter, the positions of the vias are not designated. This structure further enhances the characteristics of the antenna.

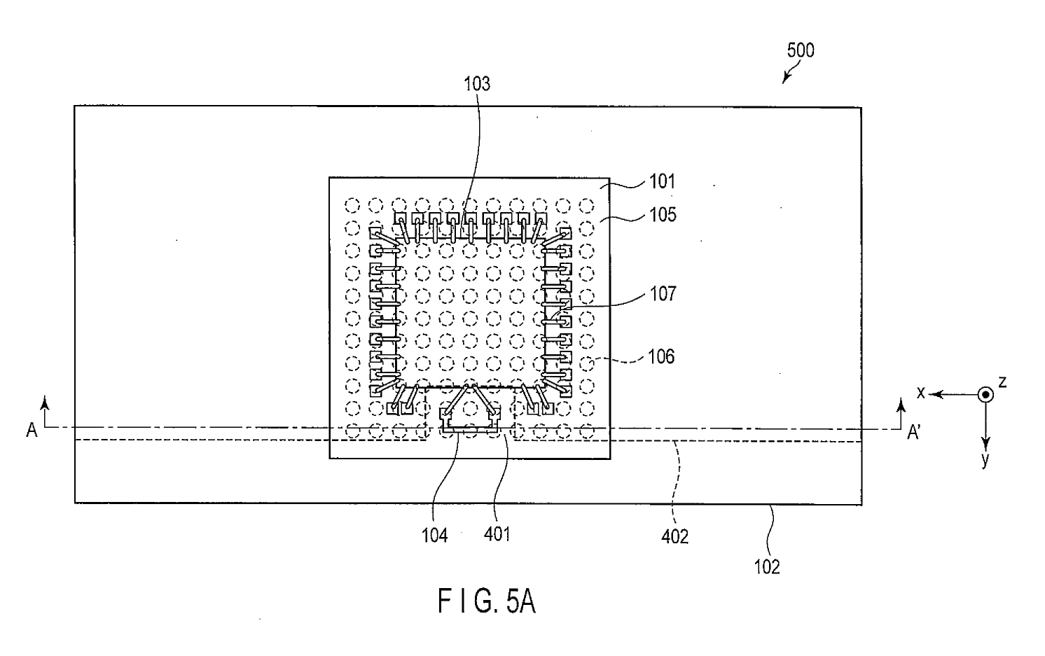

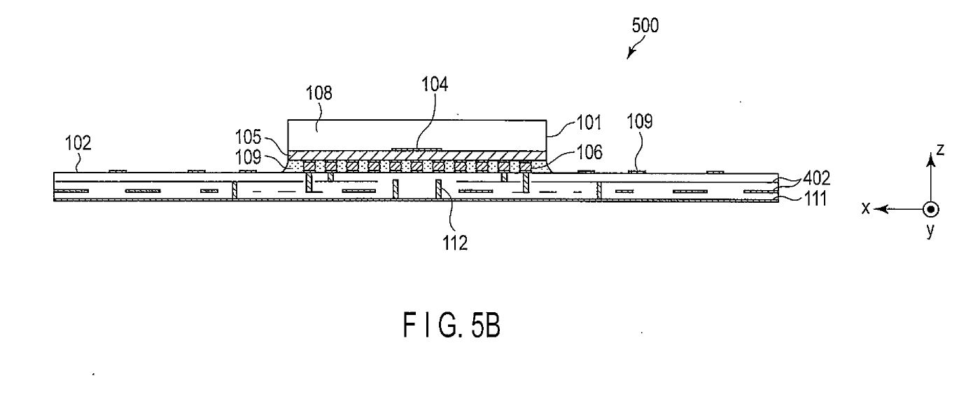

Referring to FIGS. 5A and 5B, a wireless apparatus 500 according to the third embodiment will be described. FIG. 5A is a top plan view illustrating the wireless apparatus of the third embodiment, and FIG. 5B is a sectional view taken along line A-A′ in FIG. 5A.

Since the wireless apparatus 500 of the third embodiment is similar to that of the second embodiment except for the positions of the vias 112, only the positions of the vias 112 will be described.

In the wireless apparatus 500, the vias 112 are arranged between the opposite edges of the notch 401 at regular intervals determined by the following mathematical expression (1):

n×λ/4 (1)

where n is an odd number greater than 0, and λ is the wavelength used for communication.

The distance given by the expression (1) represents an electrical length, and the “wavelength” used in the embodiment is the wavelength of a signal used by the antenna and may contain a design error.

In FIG. 5B, one end of each via 112 is connected to the first layer 111, and the other end does not reach the first surface of the board 102. However, the other end of each via 112 may be formed through the board 102 to reach the first surface.

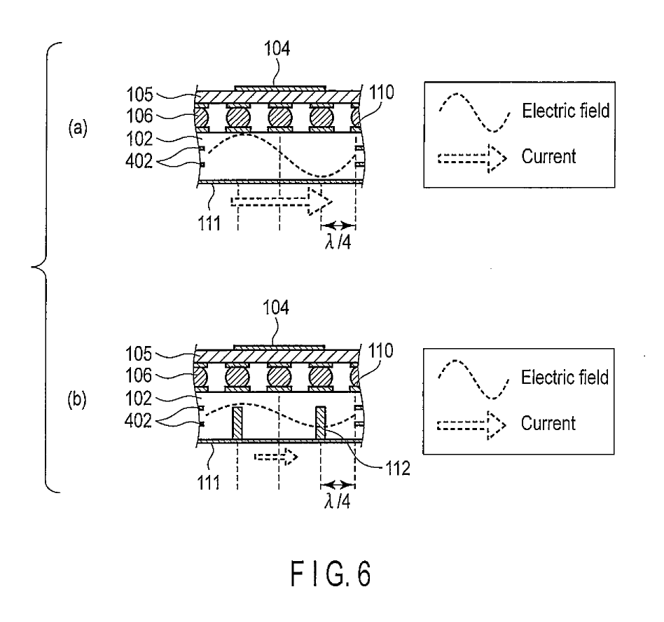

Referring then to FIG. 6, a description will be given of how the electric field and current vary depending on whether vias are provided in the wireless apparatus 500 of the third embodiment.

(a) of FIG. 6 shows the electric field and the current that occur when no vias 112 are formed, and (b) of FIG. 6 shows the electric field and the current that occur when the vias 112 are formed.

The edges of the notch 401 serve as metal walls. Accordingly, as shown in (a) of FIG. 6, the electric field occurring perpendicular to the layers of the board 102 is minimum at each edge of the notch 401, and is maximum at the distances from each edge of the notch given by the mathematical expression (1), i.e., at the distances equal to odd multiples of the quarter wavelength.

Accordingly, if the vias 112 are formed at the position, at which the electric field is maximum, as shown in (b) of FIG. 6, the electric field occurring in the board 102 and the current resulting therefrom can be suppressed, thereby preventing degradation of the radiation pattern of the antenna.

As described above, since in the third embodiment, vias are provided at the distances from an edge or opposite edges of the notch by odd multiples of the quarter wavelength, at which edge(s) the electric field is maximum, the voltage and current can be effectively suppressed, thereby further improving the characteristics of the antenna.

### Fourth Embodiment

A fourth embodiment differs from the third embodiment only in that in the former, the vias formed in a wireless apparatus 700 are connected to the external terminals 106.

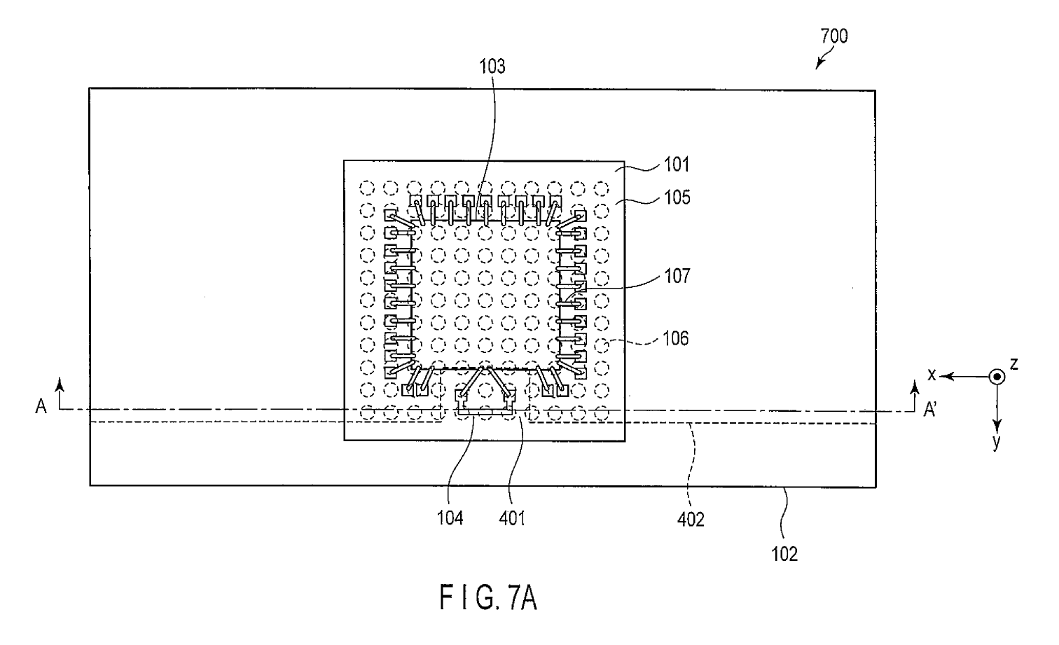

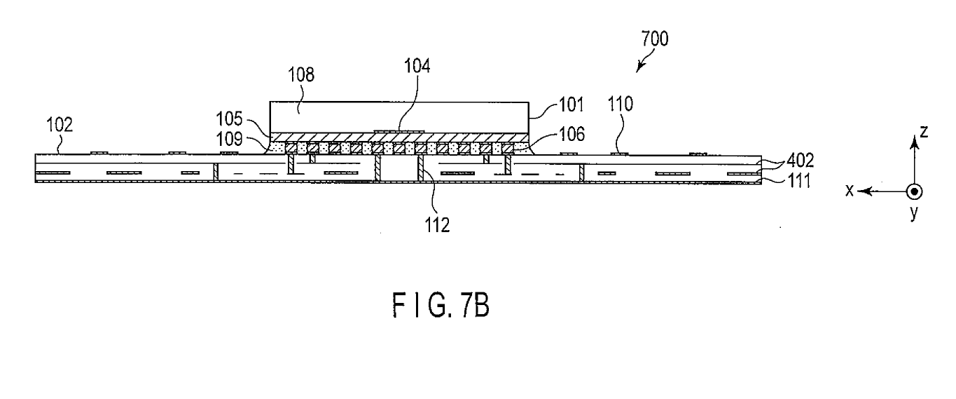

FIGS. 7A and 7B show the wireless apparatus 700 of the fourth embodiment. FIG. 7A is a top plan view of the wireless apparatus, and FIG. 7B is a sectional view taken along line A-A′ in FIG. 7A.

The wireless apparatus 700 of the fourth embodiment has substantially the same structure as the third embodiment, and is therefore not described in detail.

As shown in FIG. 7B, the first layer 111 is connected to the external terminals 106 through the vias 112.

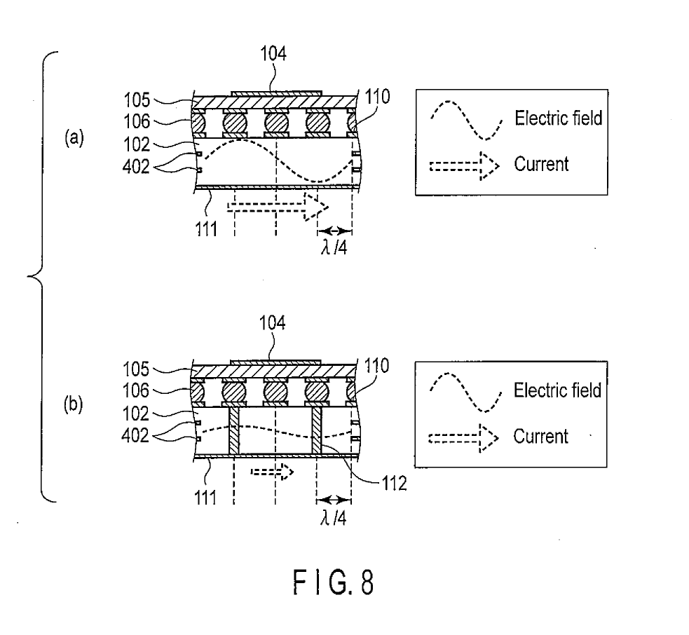

Referring then to FIG. 8, a description will be given of how the electric field and current vary depending on whether vias are provided in the wireless apparatus 700 of the fourths embodiment.

(a) of FIG. 8 shows the electric field and the current that occur when no vias 112 are formed, and (b) of FIG. 8 shows the electric field and the current that occur when the vias 112 are formed.

As shown in (b) of FIG. 8, since the vias are connected to the external terminals 106 and the first layer 111, the external terminals 106 and the first layer 111 are of the same potential, thereby significantly reducing occurrence of an electric field. In accordance with this, the occurrence of a current can also be suppressed. Thus, occurrence of the electric field and the current in the board 102 can be effectively suppressed, with the result that degradation of the radiation pattern of the antenna can be avoided.

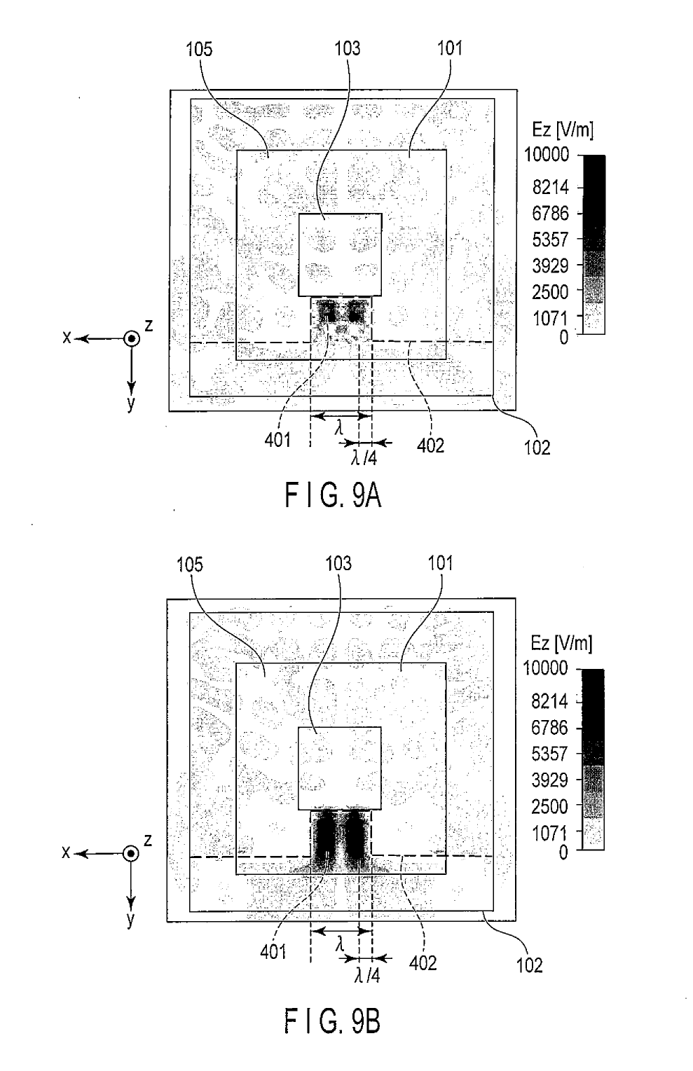

Referring now to FIGS. 9A, 9B, 10A, 10B and 11A to 11C, a description will be given of the electromagnetic fields simulated by modeling the wireless apparatus 700 of the fourth embodiment. Assume here that the notch 401 of the wireless apparatus 700 shown in FIGS. 7A and 7B has a width corresponding to the wavelength used for communication.

FIG. 9A shows the electric field component simulated in the direction (i.e., the Z-axis direction) perpendicular to the first layer 111 of the wireless apparatus 700 shown in FIGS. 7A and 7B. FIG. 9B shows the electric field component, as a comparison sample, simulated in the direction perpendicular to the first layer 111 when the wireless apparatus 700 shown in FIGS. 7A and 7B has no vias 112.

In FIG. 9B, the electric field component occurring at the board 102 in the direction perpendicular to the first layer 111 is minimum at each edge of the notch 401, and is maximum at the distances from an edge or opposite edges of the notch 401 by odd multiples of the quarter wavelength. In contrast, in the wireless apparatus 700 shown in FIG. 9A, vias 112 are provided at the distances from an edge or opposite edges of the notch 401 by odd multiples of the quarter wavelength, and are connected to the external terminals 106 and the first layer 111. As is evident from these figures, in the wireless apparatus 700 of FIG. 9A, the electric field component at the notch 401 of the board 102 is sufficiently suppressed compared to the apparatus of FIG. 9B.

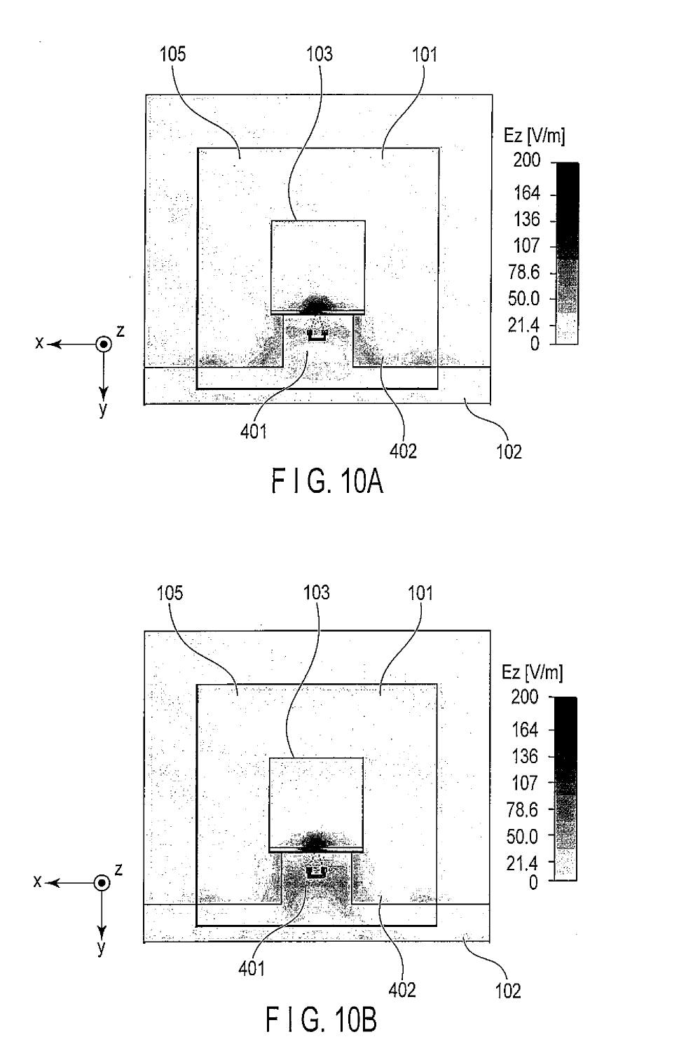

FIG. 10A shows the current component simulated in the direction (i.e., the X-axis direction) parallel to the first layer 111 of the wireless apparatus 700. FIG. 10B shows the current component, as a comparison sample, simulated in the direction parallel to the first layer 111 when the wireless apparatus 700 has no vias 112.

As in the electric field components shown in FIGS. 9A and 9B, it can be understood that in the wireless apparatus 700 of FIG. 10A, the current flowing in the notch 401 is suppressed compared to the case of FIG. 10B where there are no vias.

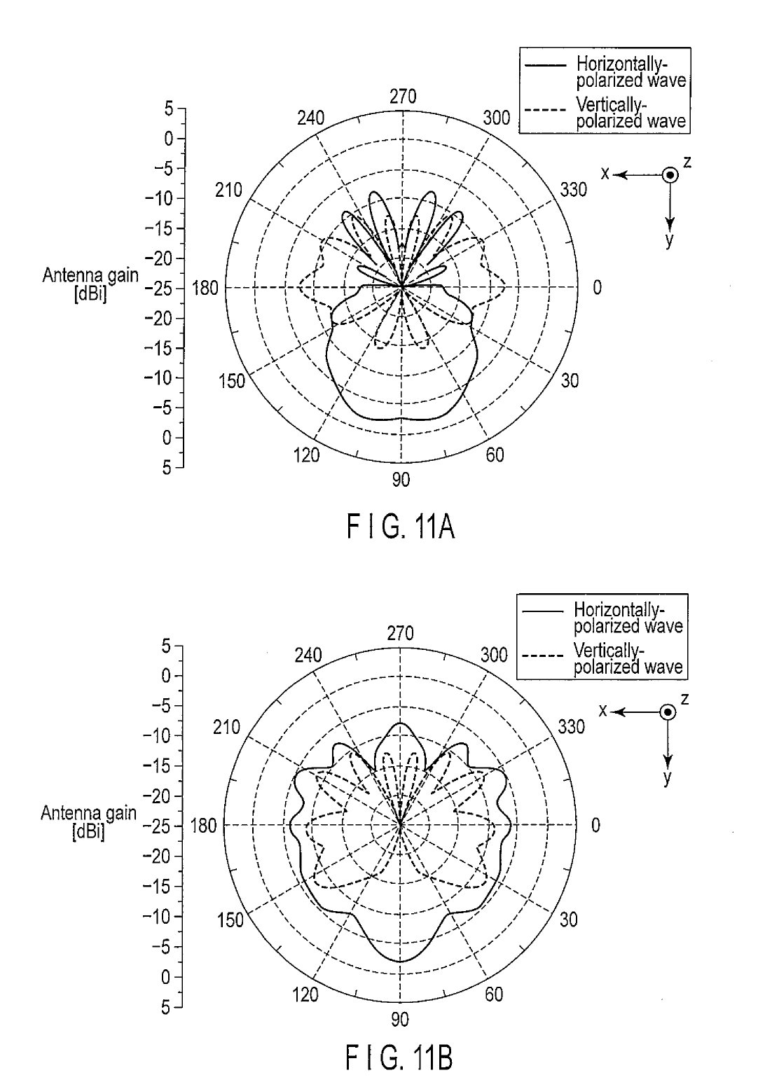

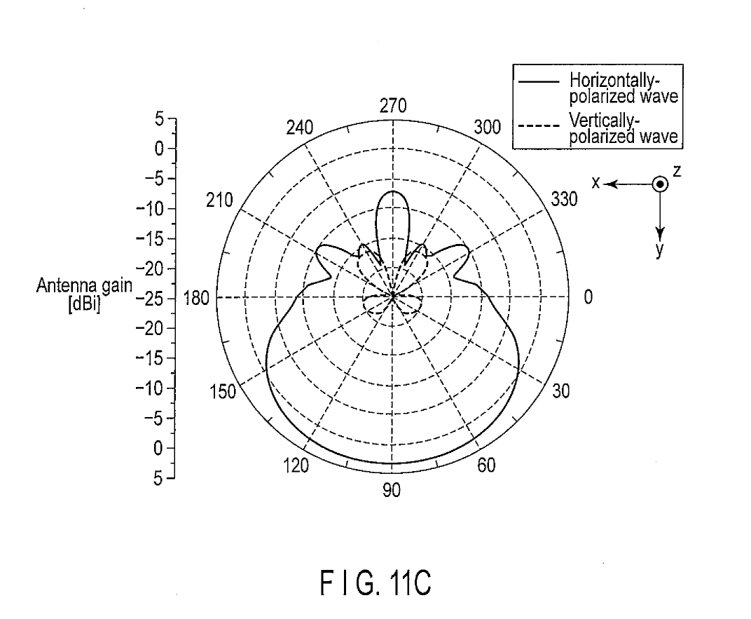

FIG. 11A shows the radiation pattern simulated on the horizontal plane (i.e., the xy plane) of the wireless apparatus 700. FIG. 11B shows the radiation pattern, as a comparison sample, simulated on the plane when the wireless apparatus 700 has no vias 112. FIG. 11C shows the radiation pattern, as another comparison sample, simulated on the plane when only the IC package 101 is incorporated in the wireless apparatus 700.

The radiation pattern of FIG. 11B significantly differs from that of FIG. 11C in that the former exhibits a high directivity in the ±y-axis directions or ±x-axis directions. In contrast, the radiation pattern of FIG. 11A is similar to that of FIG. 11C although the beam width is narrowed to some extent. From this, it can be understood that the influence of the substrate is suppressed in FIG. 11A.

Since in the above-described fourth embodiment, the vias are provided at the distances from an edge (edges) of the notch by odd multiples of the quarter wavelength and are connected to the external terminals and the first layer, the electric field and current that occur in the substrate can be effectively suppressed, thereby improving the characteristics of the antenna.

### Modification of First to Fourth Embodiments

In the above-described embodiments, the wireless apparatus includes only one antenna. However, the wireless apparatus is not limited to this, and a plurality of antennas may be included.

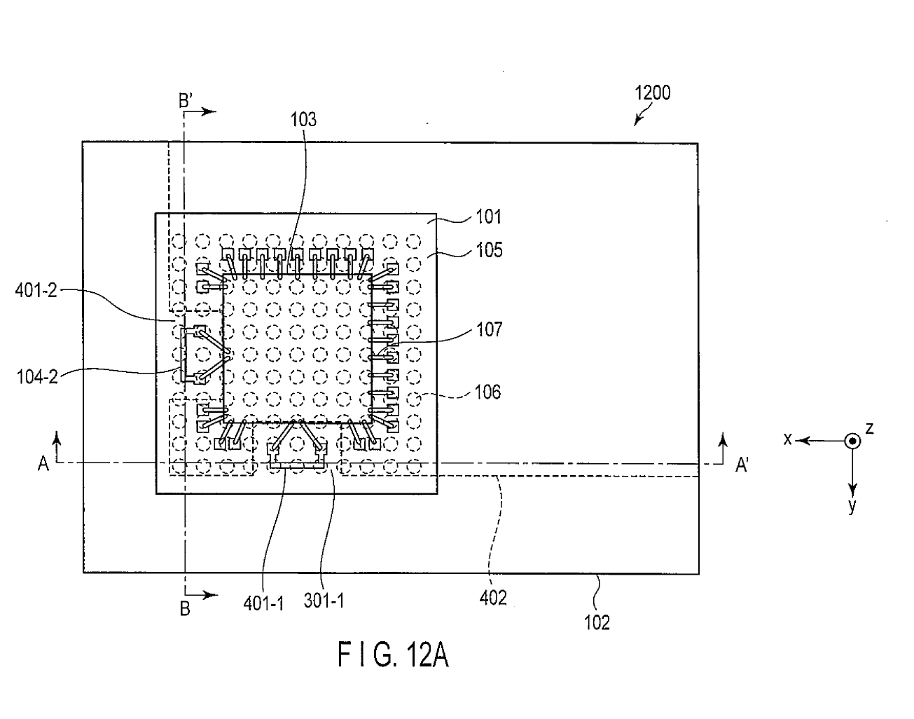

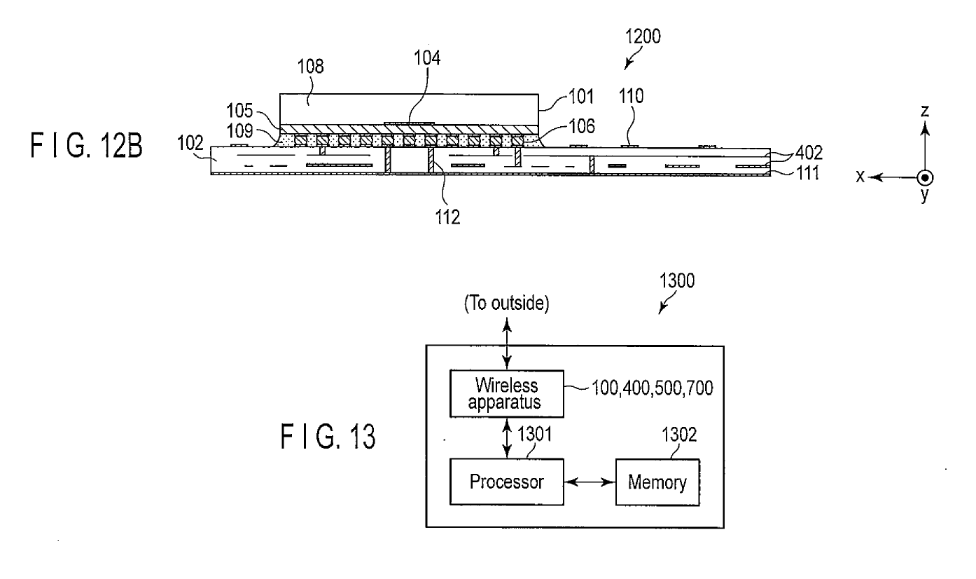

Referring to FIGS. 12A and 12B, a description will be given of a wireless apparatus 1200 that includes a plurality of antennas. FIG. 12A is a top plan view illustrating the wireless apparatus 1200, and FIG. 12B is a sectional view taken along lines A-A′ and B-B′ in FIG. 12A.

The wireless apparatus 1200 of the modification includes an IC package 101 containing two antennas 104-1 and 104-2, and a board 102 having notches 401-1 and 401-2 that include respective regions on which the antennas are projected when they are projected in the thickness direction of the board 102. Although the antennas 104-1 and 104-2 have the same shape, they may have different shapes. Further, the two antennas of the wireless apparatus 1200 may be used as an antenna array or a diversity antenna. Furthermore, the number of the antennas is not limited to two, but three or more antennas may be employed.

In the modification, the wireless apparatus 700 of the fourth embodiment is modified such that two antennas 104 are contained in the IC package 101. However, the disclosure is not limited to this, but the wireless apparatuses 100, 400 and 500 of the first to three embodiments may be modified such that a plurality of antennas 104 may be contained in the IC package 101.

### Fifth Embodiment

The above-described wireless apparatuses may be incorporated in a wireless system for exchanging data, images and/or video.

Referring the block diagram of FIG. 13, a wireless system 1300 according to a fifth embodiment will be described.

The wireless system shown in FIG. 13 includes a wireless apparatus 100, a processor 1301 and a memory 1302.

The wireless apparatus 100 exchanges data with external devices. Instead of the wireless apparatus 100, any one of the wireless apparatuses 400, 500 and 700 according to the second to fourth embodiments may be used.

The processor 1301 processes the data received from the wireless apparatus 100 or to be transmitted thereto.

The memory 1302 receives data from the processor 1301 and stores the same.

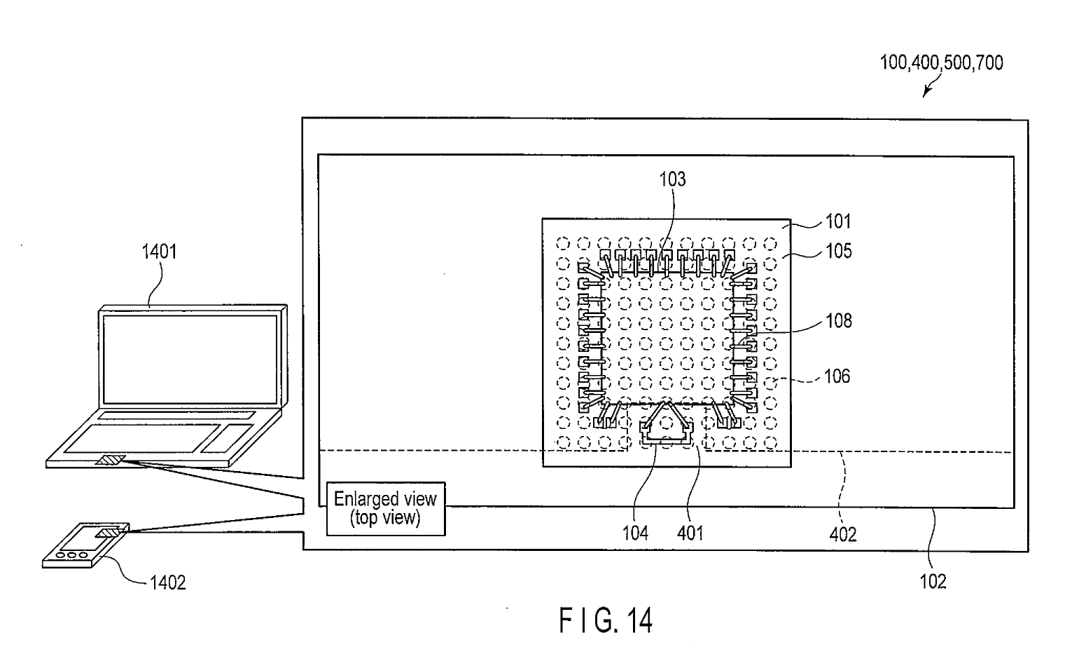

Referring then to FIG. 14, an example of a wireless system will be described.

FIG. 14 shows a note PC 1401 or a cellular phone 1402 as examples. However, the above-described wireless apparatus may be incorporated in a system, such as a TV set, a digital camera and a memory card.

The note PC 1401 and the cellular phone 1402 shown in FIG. 14 incorporate the wireless apparatus 700 of FIG. 7A as an internal or external component, and perform data communication using, for example, frequencies of a millimeter wave band. With this structure, the note PC 1401 can perform data communication with the cellular phone 1402 via the wireless apparatus 700 incorporated in the phone.

The above-described wireless systems contain metals, dielectric materials and/or various components. In this structure, if at least the region of each layer in the board 102, on which the antenna 104 is projected when it is projected in the thickness direction of the board 102, is formed of a conductor, the first layer 111 serves as a shield to reduce the influence of metals, dielectric materials or various components existing outside the first layer 111.

Further, if the wireless apparatuses incorporated in the note PC 1401 and the cellular phone 1402 are located such that the directions in which their antennas 104 exhibit a high directivity oppose each other, data communication is performed more efficiently.

In the above-described fifth embodiment, exchange of, for example, data can be performed efficiently by incorporating wireless apparatuses in wireless systems, such as the note PC or the cellular phone.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A wireless apparatus, comprising:
an integrated circuit package comprising an integrated circuit and at least one antenna;
a board having a first surface and a second surface opposite to the first surface, the integrated circuit package being mounted on the board and being electrically connected to the board; and
a first layer being formed on the second surface, a part of the first layer in a first region being formed of a conductor, the first region being a region on which the antenna is projected in a thickness direction of the board, the part of the first layer in the first region being electrically connected to a particular region included in a third region, the third region being formed of a second region included in the board and the first surface.

2. The apparatus according to claim 1, further comprising a second layer being formed in the board between the first surface and the second surface, the second layer in a fourth region including no conductor other than at least one via electrically connecting the part of the first layer in the first region to the particular region and other than a conductor used to form the via, the fourth region being a region on which the antenna is projected in a thickness direction of the board.

3. The apparatus according to claim 2, wherein the via is located in the fourth region at a distance from an outer edge of the fourth region by an odd multiple of a quarter of a wavelength.

4. The apparatus according to claim 1, wherein the integrated circuit package is electrically connected to the first layer.

5. A wireless system, comprising:
a wireless apparatus comprising, an integrated circuit package including an integrated circuit and at least one antenna, a board having a first surface and a second surface opposite to the first surface, and a first layer formed on the second surface, the integrated circuit package being mounted on the board and being electrically connected to the board, a part of the first layer in the first region being formed of a conductor, the first region being a region on which the antenna is projected in a thickness direction of the board, the part of the first layer in the first region being electrically connected to a particular region included in a third region, the third region being formed of a second region included in the board and the first surface;
a processor configured to process a data received from and to be transmitted to the wireless apparatus; and
a memory configured to store the data.

6. The system according to claim 5, wherein the wireless apparatus further comprising a second layer being formed in the board between the first surface and the second surface, the second layer in a fourth region including no conductor other than at least one via electrically connecting the part of the first layer in the first region to the particular region and other than a conductor used to form the via, the fourth region being a region on which the antenna is projected in a thickness direction of the board.

7. The system according to claim 6, wherein the via is located in the fourth region at a distance from an outer edge of the fourth region by an odd multiple of a quarter of a wavelength.

8. The system according to claim 5, wherein the integrated circuit package is electrically connected to the first layer.
